(19) United States
(12) Patent Application Publication
(10) Pub. No.: US 2007/0217180 A1
(43) Pub. Date: Sep. 20, 2007

(54) CONTROL PANEL

(76) Inventor: Jorg Schwarzbich, Bielefeld (DE)

Correspondence Address: RICHARD M. GOLDBERG, 25 EAST SALEM STREET, SUITE 419, HACKENSACK, NJ, 07601, US

(21) Appl. No.: 11/568,526

(22) PCT Filed: May 11, 2005
(86) PCT No.: PCT/EP05/05094

§ 371 Date: Oct. 31, 2006

(30) Foreign Application Priority Data
May 11, 2004 (DE) 20 2004 007 733.7

(51) Int. Cl. H05K 7/00; H01H 3/46

(52) U.S. Cl. 361/837

(57) ABSTRACT

An operating panel includes a blind (10) which supports a number of actuating elements (12, 14, 16), and a circuit substrate (18) arranged behind the blind and having switching elements (46; 48) adapted to be actuated mechanically by the operating elements, and the switching elements are located on the back side of the circuit substrate (18) facing away from the blind (10) and the operating elements (12, 14, 16) are adapted to act upon the switching elements from the back side.

The invention relates to an operating panel comprising a blind supporting a number of operating elements, and a circuit substrate that is arranged behind the blind and comprises switching elements that are adapted to be mechanically actuated by the operating elements.

Such operating panels are provided particularly on the front side of household appliances such as washing machines, dishwashers and the like. In conventional operating panels, the circuit substrate, e. g. a printed circuit board or foil is mounted on a separate bracket that is arranged to behind the blind and spaced away from the latter. The operating elements, e. g. push-buttons or rotary knobs, penetrate the blind and then act upon the switching elements on the circuit substrate from the front side, as is shown for example in EP 1 008 160 B1.

Since the blind must necessarily have through-holes for the individual operating elements, there is a risk that moisture enters from the outside through the through-holes onto the circuit substrate and then causes short-circuits or other malfunctions in the electronic circuit.

It is an object of the invention to provide an operating panel wherein the electronic circuit is better protected against the intrusion of moisture from the outside.

According to the invention, this object is achieved by the feature that the switching elements are arranged on the back side of the circuit substrate facing away from the blind, and that the operating elements are adapted to act upon the switching elements from the back side.

Thus, since the switching elements and the conductors associated therewith as well as other electronic components of the circuitry are arranged on the side of the circuit substrate that is facing away from the blind, they are shielded from the direct action of moisture that may intrude from the outside. The operating elements must reach through or around the circuit substrate, so that they may act upon the circuit elements from the back side. Nevertheless, the circuit substrate forms an additional barrier that significantly reduces the probability that splashed water, condensated water or the like reaches the back side of the circuit substrate.

It is another substantial advantage of the invention that the structure and the manufacture of the operating panel are simplified. In order for the operating elements to be able to act mechanically upon the circuit elements, for example by directly or indirectly closing an electrical contact, the switching elements and the circuit substrate, respectively, must be supported by a suitable backing member. This backing member has heretofore been formed by the bracket. In contrast, in the construction according the invention, the backing member must be provided on the front side of the circuit substrate, and it may thus be formed directly by the blind itself. This is why, in a preferred embodiment, the circuit substrate is attached to the blind, so that an additional bracket may be dispensed with.

Other useful features of the invention are indicated in the dependent claims.

When the operating elements are formed by push-button keys, it is generally necessary to revert the direction of motion, so that the pressure that a user exerts upon the key may be translated into an operating force that acts upon the associated switching element from the back side and exerts a pressure thereon that is directed towards the blind. This reversal of motion may for example be achieved by means of a rocker lever. In a particularly preferred embodiment, the push-button key, the rocker lever and the fulcrum for the rocker lever are formed in one piece from plastics, so that a key unit is formed that can easily be handled and may be mounted to the back side of the blind or, alternatively, to the back side of the circuit substrate. When the key unit is mounted to the blind, it may at the same time serve for fixing the circuit substrate.

In a preferred embodiment, the key unit that is made in one piece from plastics comprises a base plate in which a rocker lever is defined by two U-shaped slots, and one arm of the rocker lever carries the push-button, and the other arm carries a pressing member for actuating the circuit element. Optionally, this second arm may also carry a stop for limiting the key stroke. The two U-shaped slots have their open ends facing towards each other and are so arranged that their legs overlap, but are separated by a web that may be configured as a flexible hinge and forms the fulcrum-type support for the rocker lever.

Optionally, the one-piece key unit may also comprise a plurality of rocker levers each of which carries one key.

When the operating element is formed by a rotary knob, it preferably comprises an axle that is rotatably supported in the blind and also penetrates the circuit substrate and carries, at its rear end, a disk that straddles the circuit substrate. On the side facing the circuit substrate, this disk may be provided with pressing members, electrical contacts and the like for actuating the circuit elements. A simple assembly process is made possible by initially forming the rotary knob and said disk as separate members that are attached to the blind from opposite sides during the assembly process and are then connected to one another, for example through snap-action.

In order to further obstruct the entry of moisture, the through-hole in the blind that is provided for the key or the rotary knob may be surrounded by a splash baffle that is formed integrally with the blind. This splash baffle may be utilised for mounting the key unit and for mounting and/or forming detents for the rotary knob, respectively.

Embodiment examples of the invention will now be explained in conjunction with the drawings, wherein:

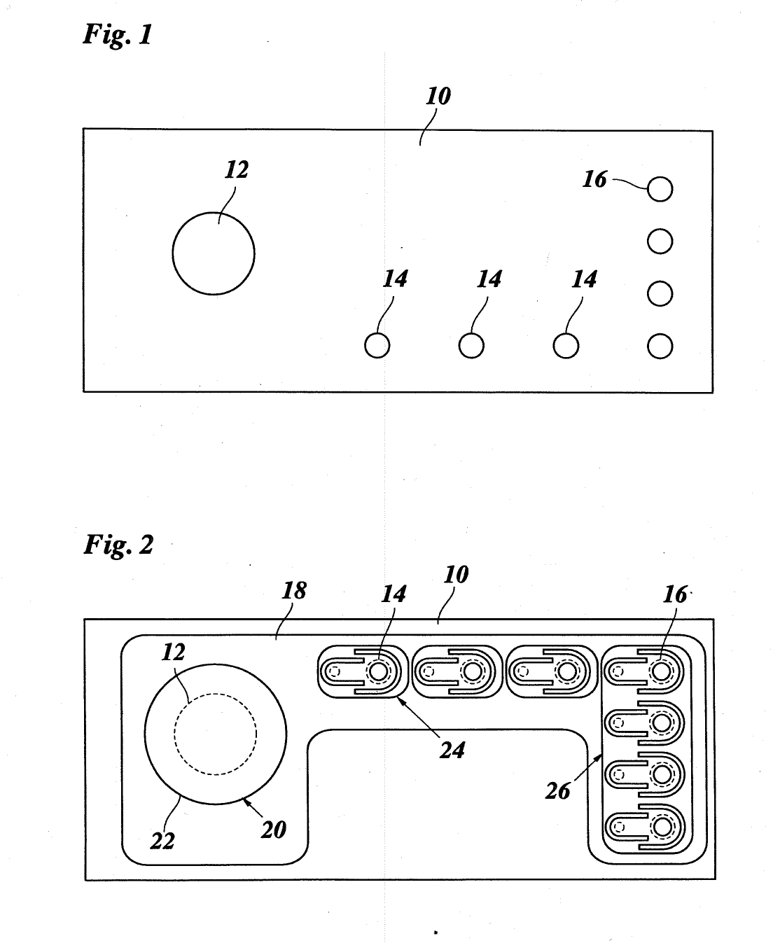

FIG. 1 is a front view of an operating panel;

FIG. 2 is a rear view of the operating panel;

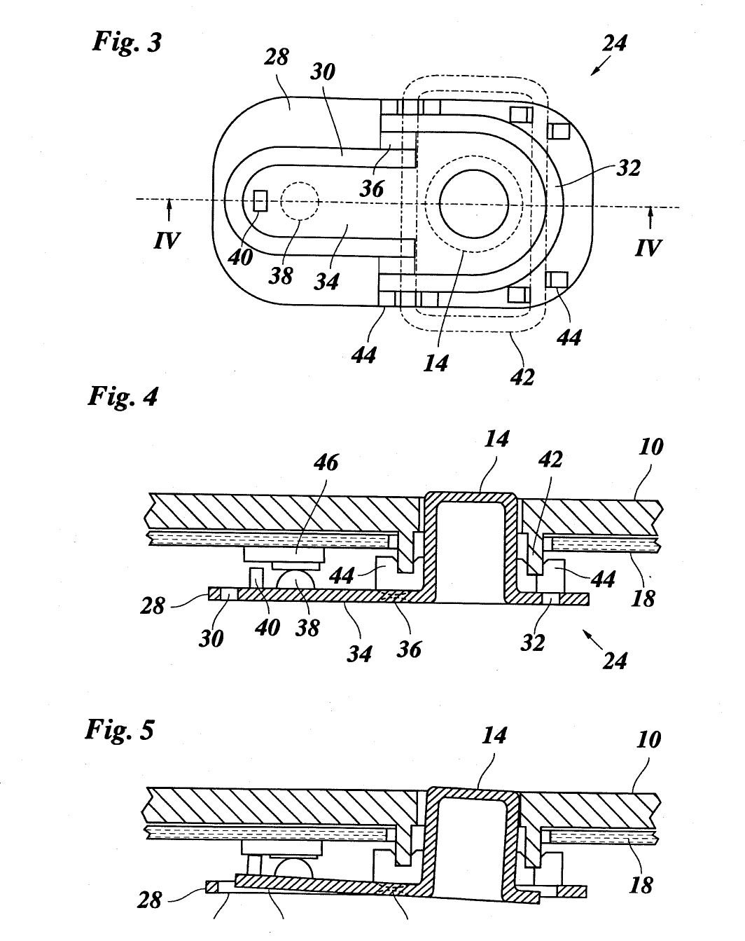

FIG. 3 is an enlarged rear view of a key unit;

FIG. 4 is a sectional view of the key unit taken along the line IV-IV in FIG. 3;

FIG. 5 is a sectional view corresponding to FIG. 4 and showing the actuated condition of the key unit;

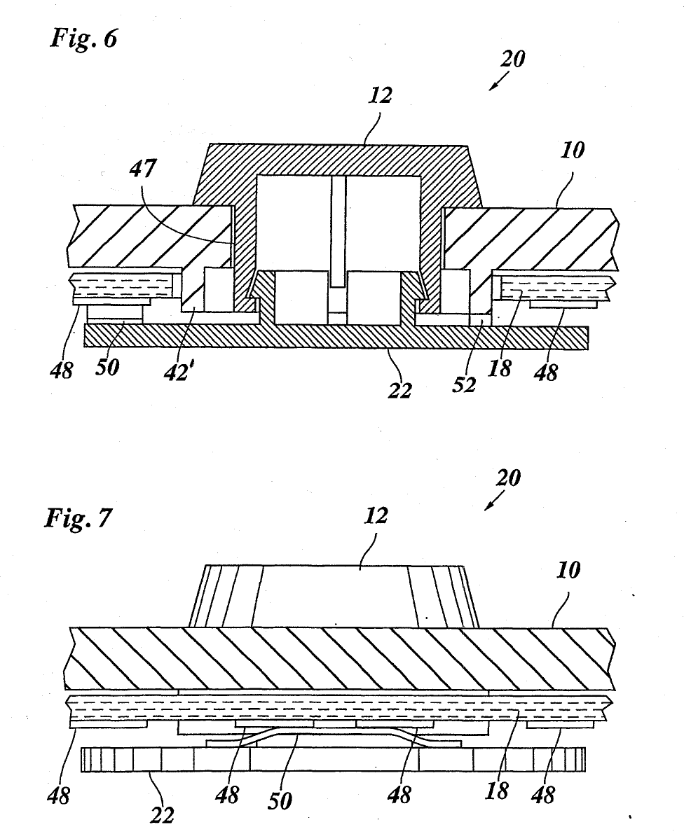

FIG. 6 is an axial section of a rotary knob unit; and

FIG. 7 is a side elevation of the rotary knob unit shown in FIG. 6.

The operating panel shown in FIG. 1 comprises a plate-like blind 10 that is formed for example from plastics by injection molding and supports a rotary knob 12, several single keys 14 and a group of four further keys 16.

FIG. 2 is a view of the blind 10 from the rear side of which a planar circuit substrate 18 is attached, for example by means of an adhesive.

The circuit substrate may for example be an FPC-film carrying printed conductors, that have not been shown, as well as other electrical components of an electronic circuit for processing commands that are input by means of the rotary knob 12 and the keys 14, 16. The rotary knob 12 forms part of a rotary knob unit 20 penetrating the blind 10 and the circuit substrate 18 and of which only a disk 22 is visible in FIG. 2. Each of the keys 14 forms part of a separate key unit 24, whereas the keys 16 form part of a common key unit 26.

FIG. 3 is an enlarged view of one of the key units 24. This key unit is a one-piece-plastic member and comprises a base plate 28 wherein a rocker lever 34 is defined by two U-shaped slots 30, 32. The end portions of the legs of the two U-shaped slots 30, 32 overlap one another, but are separated by webs that are configured as flexible hinges 36 and form a fulcrum for the rocker lever. The arm of the rocker lever 34 on the right side in FIG. 3 has a bulge that forms the key 14, as is seen more clearly in FIG. 4. The other arm of the rocker lever 34 is provided, on the side facing the circuit substrate 18, with a pressing member 36 and a stop 40 at the free end of the arm.

The inner side of the blind 10 (bottom side in FIG. 4) has a splash baffle 42 that surrounds the through-hole formed in the blind for accommodating the key 14 and prevents splashed water from passing through the through-hole and reaching the bottom side of the circuit substrate 18 in FIG. 4. In the example shown, the peripheral portion of the base plate 28 is formed with supports 44 with which the key unit is plugged onto the splash baffle 42.

The above mentioned conductors and circuit components of the electronic circuitry are located on the side of the circuit substrate 18 that is the bottom side in FIG. 4. Among others, these circuit components comprise a switching element that is configured as a push-button switch 46 and arranged to be opposed to the pressing member 38.

When a finger pressure is applied onto the key 14 from above, the rocker lever 34 tilts about the axis defined by the flexible hinges 36, as is shown in FIG. 5, and the push-button switch is actuated by the pressing member 38. The stop 40 abuts against the casing of the switch and thereby limits the key stroke. When the key 14 is released, it elastically returns into the position shown in FIG. 4, due to the elasticity of the flexible hinges 36.

The key unit 26 has a similar construction, with the only difference that a single base plate comprises several rocker levers for the keys 16.

In FIG. 6, the rotary knob unit 20 shown in FIG. 2 has been illustrated in an axial section. The rotary knob 12 forms an axle 46 which passes through the blind 10 and is snap-locked to the disk 22 in a manner assuring corotation and tensile strength in axial direction. The axle 46 is rotatably supported in a through-hole of the blind 10, and this through-hole is again surrounded by a splash baffle 42 projecting through a hole of the circuit substrate 18. In this example, the switching elements on the circuit substrate 18 are simply formed by the ends of conductors 48 that extend into the area covered by the disk 22 and between which electrically conductive connections may be formed by contact bridges 50 formed on the disk 22, depending upon the position of the rotary knob 12, as can be seen more clearly in FIG. 7. The contact bridges 50 are formed as elastic springs, so that the necessary contact pressure may be provided. The reaction force of the contact bridges is transmitted through the disk 22 onto the rotary knob 12 which is supported on the front side of the blind 10. Defined detent positions for the rotary knob 10 may for example be obtained by providing one or more detent cams 52 distributed on the periphery of the disk 22 so as to engage detent notches (not shown) in the end-face of the splash baffle 42.

Optionally, the contact bridges 50 on the disk 22 may be replaced with switching cams that actuate corresponding switching elements on the circuit substrate 18. Then, these switching elements may also define the detent positions for the rotary knob. Likewise is it possible to incorporate in the axle 46 a spring mechanism which pulls the disk 22 in the direction towards the blind 10 so as to create the necessary pressure for actuating the switching elements. Optionally, spring elements, which pull the rotary knob 12 and the disk 22 upwards (in FIG. 6) as a unit, may also be provided on the surfaces with which the rotary knob 12 is supported on the front side of the blind 10.

An alternative way to provide detent positions for the rotary knob 10 is to provide locking teeth on the internal surface of the splash baffle 42, said teeth cooperating with elastic tongues projecting from the disk 22. These tongues may at the same time serve for mechanically locking the disk 22 to the splash baffle, so that no drag is exerted onto the rotary knob 10 and, consequently, the friction between the edge of the rotary knob 10 and the front side of the blind 10 is reduced.

A key switch without rocking lever may be embodied in analogy to the construction of the rotary knob unit 20. Then, in place of the rotary knob 12, there would be provided a key that is elastically biased upwardly and carries on the inner side of the circuit substrate 18 a disk which corresponds to the disk 22 and is provided with pressing members for actuating the switching elements. The difference in comparison to the arrangement shown in FIG. 4 would be that, in this case, the switching elements are constantly engaged by the pressing member in the non-actuated state, and the pressing member releases the switching elements only when the key is actuated.

Whereas, in the embodiments shown, the entry of splashed water is prevented by the splash baffle 42, it is also possible in an alternative embodiment to seal the gaps between the operating elements 12, 14, 16 and the blind 10 by suitable seal members. However, in the arrangement shown in FIG. 4, the seal member for the key 14 should be resilient and have a low friction, so that the movement of the key for tilting the rocker lever 34 is not obstructed.

What is claimed is:

1. Operating panel comprising:
a blind which supports a number of operating elements,
a circuit substrate arranged behind the blind, and
switching elements adapted to be actuated mechanically by the operating elements, the switching elements being located on a back side of the circuit substrate facing away from the blind and the operating elements are adapted to act upon the switching elements from the back side.

2. Operating panel according to claim 1, wherein the circuit substrate (18) is attached to the blind.

3. Operating panel according to claim 1, wherein the blind forms a backing member for the circuit substrate.

4. Operating panel according to claim 1, wherein at least one said operating element is configured as a key and includes a rocker lever transmitting movement of the key onto a respective said switching element.

5. Operating panel according to claim 4, wherein the rocker lever is formed by a portion of a base plate defined by two U-shaped slots, and legs of the two slots are separated by webs that act as flexible hinges and form a fulcrum for the rocker lever.

6. Operating panel according to claim 5, wherein the rocker lever and the key are formed in one piece.

7. Operating panel according to claim 1, wherein at least one said operating element is configured as a rotary knob having an axle which penetrates the blind and the circuit substrate and carries, on a back side of the circuit substrate, a disk which straddles the circuit substrate and has actuator elements for actuating the switching elements on the circuit substrate.

8. Operating panel according to claim 7, wherein each rotary knob is surrounded individually by a splash baffle molded to a back side of the blind.

9. Operating panel according to claim 7, wherein each rotary knob is surrounded in groups, by a splash baffle molded to a back side of the blind.

10. Operating panel according to claim 4, wherein each key is surrounded individually, by a splash baffle molded to a back side of the blind.

11. Operating panel according to claim 4, wherein each key is surrounded in groups, by a splash baffle molded to a back side of the blind.
